(19) United States
(12) Patent Application Publication
(10) Pub. No.: US 2025/0151199 A1
(43) Pub. Date: May 8, 2025

(54) Apparatus and Method for Improving Micro-Inverter Longevity

(71) Applicant: AA Power Inc., Boston, MA (US)

(72) Inventor: Qun Lu, Lexington, MA (US)

(21) Appl. No.: 18/423,262

(22) Filed: Jan. 25, 2024

Related U.S. Application Data
(60) Provisional application No. 63/547,813, filed on Nov. 8, 2023.

(51) Int. Cl. H05K 1/18; H02M 7/00; H05K 7/20

(52) U.S. Cl. CPC H05K 1/181; H02M 7/003; H05K 7/2039; H05K 2201/10015; H05K 2201/10053

(57) ABSTRACT

An apparatus includes a first component group on a first board, a second component group on a second board, wherein components of the first component group are heat-generating elements configured to generate more heat than components of the second component group, and a plurality of connecting elements electrically coupled between the first component group and the second component group, wherein portions of the plurality of connecting elements are in a thermal resistance medium, and the first component group and the second component group are separated by the thermal resistance medium.

### RELATED APPLICATION

This application claims the benefit of U.S. Provisional Application No. 63/547,813, filed on Nov. 8, 2023, entitled “Apparatus and Method for Improving Micro-Inverter Longevity,” which application is hereby incorporated herein by reference.

### TECHNICAL FIELD

The present invention relates to an apparatus and method for improving the longevity of power conversion devices, and, in particular embodiments, to an apparatus and method for improving the longevity of micro-inverters through mounting heat-generating components and non-heat-generating components on different boards and separating the heat-generating components and non-heat-generating components through a thermal resistance medium.

### BACKGROUND

A renewable energy system comprises a plurality of power sources that generate direct current (dc) power and a power conversion system. The plurality of power sources may be a plurality of solar panels. The power conversion system converts the dc power into alternating current (ac) power. The ac power may be fed into the power grid. The power grid coupled to the renewable energy system has an ac voltage of about 240 volts at 60 Hz.

In some solar energy applications, a single inverter may convert the de output voltages of a plurality of solar panels to an ac voltage. The plurality of solar panels may be connected in series, and then connected to a central inverter. The central inverter converts the dc voltage from the series-connected solar panels into an ac voltage suitable for the power grid. An alternative approach is to use a single micro-inverter with each solar panel. A micro-inverter is a system that converts the de voltage from a single solar panel to an ac voltage. The electric power from several micro-inverters is combined and fed into the power grid.

A micro-inverter comprises an input filter, a dc/dc power converter such as a boost converter, various bus capacitors, a PWM dc/ac inverter, an output filter, a control unit and various sensing and protection circuits. The dc/dc power converter may be implemented as an isolated interleaved booster converter. The dc/dc power converter comprises various heat-generating components such as power switches and the isolation transformer. The PWM dc/ac inverter also comprises various heat-generating components such as power switches. The input filter may comprise one electrolytic capacitor or a plurality of electrolytic capacitors connected in parallel. The micro-inverter may be packaged in a module.

FIG. 1 illustrates a micro-inverter module. The micro-inverter comprises a plurality of components (e.g., power switches, transformers, inductors, various capacitors and control circuits) mounted on a printed circuit board (e.g., a single or multilayer fiberglass printed circuit board, a single or multilayer ceramic printed circuit board and the like). The printed circuit board is packaged in a case. An encapsulant (e.g., a potting compound material) is filled into the case. In particular, the encapsulant is formed about the plurality of components to substantially surround the plurality of components. The encapsulant may be a thermosetting epoxy potting compound. Once the encapsulant has filled the case, a brick power conversion module 100 is formed as shown in FIG. 1.

In the existing micro-inverters, all electronic components are encapsulated with a thermosetting epoxy potting compound. The temperature is transmitted from the inside to the outside. As a result, the temperature inside the case must be higher than the temperature of the case of the micro-inverter module. For example, if the temperature of the outer case of the brick power conversion module 100 is about 100 degrees, the temperature inside the module might be about 120 degrees. The high temperature inside the brick power conversion module 100 may hurt the longevity of some components (e.g., electrolytic capacitors or control circuits) vulnerable to overheating. Therefore, the existing micro-inverters cannot easily satisfy the 25-year life requirements of existing solar applications.

The lifespan of electronic components is directly related to the temperature. The operating temperature has a significant impact on the performance, safety and lifetime of electronic components. Basically, every time the temperature increases by ten degrees, the lifespan of the electronic components is reduced by half. If the temperature of electronic components can be lowered, the lifespan will be improved. The present disclosure addresses this need.

### SUMMARY

These and other problems are generally solved or circumvented, and technical advantages are generally achieved, by preferred embodiments of the present disclosure which provide an apparatus and method for improving the longevity of micro-inverters through mounting heat-generating components and non-heat-generating components on different boards and separating the heat-generating components and non-heat-generating components through a thermal resistance medium.

In accordance with an embodiment, an apparatus comprises a first component group on a first board, a second component group on a second board, wherein components of the first component group are heat-generating elements configured to generate more heat than components of the second component group, and a plurality of connecting elements electrically coupled between the first component group and the second component group, wherein portions of the plurality of connecting elements are in a thermal resistance medium, and the first component group and the second component group are separated by the thermal resistance medium.

In accordance with another embodiment, a micro-inverter comprises power switches and magnetic devices on a first board, a control integrated circuit on a second board, and a plurality of connecting elements electrically coupled between the first board and the second board, wherein portions of the plurality of connecting elements are in a thermal resistance medium.

In accordance with yet another embodiment, a method comprises providing a power conversion system comprising a first board, a first component group over the first board, a second board, a second component group over the second board and a plurality of connecting elements between the first board and the second board, forming a first potting compound layer over the first board using a first liquid potting compound material, wherein a topmost surface of the first component group is lower than a top surface of the first potting compound layer, hardening the first potting compound layer, forming a second potting compound layer over the first potting compound layer using a second liquid potting compound material, wherein a bottommost surface of the second component group is higher than a top surface of the second potting compound layer, hardening the second potting compound layer, forming a third potting compound layer over the second potting compound layer using a third liquid potting compound material, wherein a topmost surface of the third potting compound layer is in contact with the second board, and hardening the third potting compound layer.

The foregoing has outlined rather broadly the features and technical advantages of the present disclosure in order that the detailed description of the disclosure that follows may be better understood. Additional features and advantages of the disclosure will be described hereinafter which form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 illustrates a micro-inverter module;

FIG. 2 illustrates a block diagram of a power conversion module in accordance with various embodiments of the present disclosure;

FIG. 3 illustrates a first implementation of the power conversion module shown in FIG. 2 in accordance with various embodiments of the present disclosure;

FIG. 4 illustrates the implementation of the first component group and the second component group shown in FIG. 3 in accordance with various embodiments of the present disclosure;

FIG. 5 illustrates a second implementation of the power conversion module shown in FIG. 2 in accordance with various embodiments of the present disclosure;

FIG. 6 illustrates a third implementation of the power conversion module shown in FIG. 2 in accordance with various embodiments of the present disclosure;

FIGS. 7 and 8 illustrate a fourth implementation of the power conversion module shown in FIG. 2 in accordance with various embodiments of the present disclosure; and

FIG. 9 illustrates a flow chart of a method for fabricating the power conversion apparatus shown in FIG. 6 in accordance with various embodiments of the present disclosure.

Corresponding numerals and symbols in the different figures generally refer to corresponding parts unless otherwise indicated. The figures are drawn to clearly illustrate the relevant aspects of the various embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that the present disclosure provides many applicable inventive concepts that can be embodied in a wide variety of specific contexts. The specific embodiments discussed are merely illustrative of specific ways to make and use the disclosure, and do not limit the scope of the disclosure.

The present disclosure will be described with respect to preferred embodiments in a specific context, namely an apparatus and method for improving the longevity of micro-inverters through mounting heat-generating components and non-heat-generating components on different boards and separating the heat-generating components and non-heat-generating components through a thermal resistance medium. The disclosure may also be applied, however, to a variety of power conversion systems such as outdoor uninterruptible power supply (UPS) systems, on-board chargers for electric vehicle (EV) applications, outdoor telecommunication power supplies, communication base station power supplies, solar optimizers, high power motor drive inverters and the like. Hereinafter, various embodiments will be explained in detail with reference to the accompanying drawings.

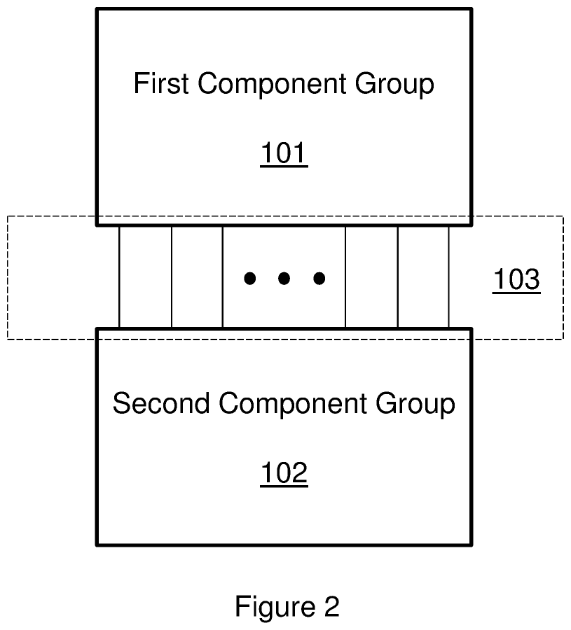

FIG. 2 illustrates a block diagram of a power conversion apparatus in accordance with various embodiments of the present disclosure. In some embodiments, the power conversion apparatus is a micro-inverter. The micro-inverter comprises a first component group 101, a second component group 102 and a plurality of connecting elements 103. In some embodiments, the first component group 101 is on a first board. The second component group 102 is on a second board. Components of the first component group 101 comprise heat-generating elements configured to generate more heat than components of the second component group 102. In the micro-inverter, power switches and magnetic devices (e.g., transformer and/or inductor) are considered as the heat-generating elements of the micro-inverter. The rest components are considered as the non-heat-generating elements. Depending on different applications and design needs, some capacitors may be considered as the heat-generating elements. For example, the resonant capacitor of an inductor-inductor-capacitor (LLC) resonant converter may be considered as a heat-generating element because a large amount of current flows through the resonant capacitor.

The plurality of connecting elements 103 is electrically coupled between the first component group 101 and the second component group 102. Portions of the plurality of connecting elements 103 are in a thermal resistance medium. As shown in FIG. 2, the first component group 101 and the second component group 102 are separated by the thermal resistance medium.

In some embodiments, the plurality of connecting elements 103 may be implemented as a plurality of cables configured to conduct a plurality of signals and/or power between the first board and the second board. In alternative embodiments, at least some thermally conductive signal cables are replaced by one or a plurality of wireless communication channels through which some control signals flow between the first board and the second board. Furthermore, at least some thermally conductive power cables are replaced by one or a plurality of wireless power transfer channels. For example, bias power may be transferred from the second board to the first board. The bias power can be transferred using a wireless power transfer channel comprising a transmitter circuit, a transmitter coil, a receiver coil magnetically coupled to the transmitter coil and a receiver circuit.

In some embodiments, the thermal resistance medium is air. In alternative embodiments, the thermal resistance medium may be suitable thermal resistance materials filled between the first component group 101 and the second component group 102.

In some embodiments, the first board is a fast heat-conducting board. The second board is a printed circuit board. In some embodiments, the fast heat-conducting board is thermally conductive and electrically isolating ceramic printed circuit board. In alternative embodiments, the fast heat-conducting board is a thermally conductive and electrically isolating metal board having a metallic support plate, a dielectric layer over the metallic support plate and a circuit layer over the dielectric layer. The metallic support plate is made of suitable metals such as aluminum. The circuit layer is made of suitable metals such as copper.

In some embodiments, the components of the first component group 101 include heat-generating components such as power switches. The components of the second component group include a plurality of integrated circuits and at least one electrolytic capacitor. The first component group is in a first module.

In a first implementation of the micro-inverter, the micro-inverter comprises an input filter coupled to a photovoltaic panel, a single-stage dc/ac inverter without galvanic isolation and an output filter. The input filter comprises at least one electrolytic capacitor. The single-stage dc/ac inverter may be implemented as a full-bridge dc/ac inverter comprising four power switches. The electrolytic capacitor is coupled to the photovoltaic bus. The electrolytic capacitor is employed to control the voltage ripple across the photovoltaic bus.

In the first implementation of the micro-inverter, the components of the first component group 101 may comprise the power switches of the of the single-stage dc/ac inverter and the inductor of the output filter. For convenience of layout and compactness, the gate drivers of the power switches and the output capacitor of the output filter may be also included in the first component group 101. The electrolytic capacitor, the integrated circuits for controlling the single-stage dc/ac inverter and passive components associated with the integrated circuits are included in the second component group 102.

As shown in FIG. 2, the first component group 101 and the second component group 102 are separated by a thermal resistance medium (e.g., air). As a result, the heat-generating components (e.g., power switches) and non-heat-generating components (e.g., integrated circuits) are separated by the thermal resistance medium. Therefore, the heat-generating components do not cause a significant temperature rise on the non-heat-generating components vulnerable to overheating.

In a second implementation of the micro-inverter, the micro-inverter comprises an input filter coupled to a photovoltaic panel, a single-stage dc/ac inverter without galvanic isolation and an output filter. The input filter does not comprise electrolytic capacitors. Other suitable capacitors such as tantalum capacitors, ceramic capacitors and the like are employed to replace the electrolytic capacitors. The single-stage dc/ac inverter may be implemented as a full-bridge inverter comprising four power switches.

In the second implementation of the micro-inverter, the components of the first component group 101 may comprise the power switches of the of the single-stage dc/ac inverter and the inductor of the output filter. For convenience of layout and compactness, the capacitors of the input filter, the gate drivers of the power switches and the output capacitor of the output filter may be also included in the first component group 101. The integrated circuits for controlling the single-stage dc/ac inverter and passive components associated with the integrated circuits are included in the second component group 102. Similar to the first implementation, the heat-generating components (e.g., power switches) and non-heat-generating components (e.g., integrated circuits) are separated by the thermal resistance medium. Therefore, the heat-generating components do not cause a significant temperature rise on the non-heat-generating components vulnerable to overheating.

In a third implementation of the micro-inverter, the micro-inverter comprises an input filter coupled to a photovoltaic panel, a single-stage dc/dc converter without galvanic isolation, a dc link, a dc/ac inverter without galvanic isolation and an output filter. The input filter comprises at least one electrolytic capacitor. The single-stage dc/dc converter may be implemented as a boost converter. The dc/ac inverter may be implemented as a full-bridge dc/ac inverter. The electrolytic capacitor is coupled to the photovoltaic bus.

In the third implementation of the micro-inverter, the components of the first component group 101 may comprise the power switches and the inductor of the of the single-stage dc/dc converter, the power switches of the of the dc/ac inverter and the inductor of the output filter. For convenience of layout and compactness, the gate drivers of the power switches, the capacitors of the dc link and the output capacitor of the output filter may be also included in the first component group 101. The electrolytic capacitor, the integrated circuits for controlling the single-stage dc/dc converter and the dc/ac inverter, and passive components associated with the integrated circuits are included in the second component group 102. Similar to the first implementation, the heat-generating components (e.g., power switches) and non-heat-generating components (e.g., integrated circuits) are separated by the thermal resistance medium. Therefore, the heat-generating components do not cause a significant temperature rise on the non-heat-generating components vulnerable to overheating.

In a fourth implementation of the micro-inverter, the micro-inverter comprises an input filter coupled to a photovoltaic panel, a single-stage dc/dc converter without galvanic isolation, a dc link, a dc/ac inverter without galvanic isolation and an output filter. The input filter does not comprise electrolytic capacitors. Other suitable capacitors such as tantalum capacitors, ceramic capacitors and the like are employed to replace the electrolytic capacitors. The single-stage dc/dc converter may be implemented as a boost converter. The dc/ac inverter may be implemented as a full-bridge inverter.

In the fourth implementation of the micro-inverter, the components of the first component group 101 may comprise the power switches and the inductor of the of the single-stage dc/dc converter, the power switches of the of the dc/ac inverter and the inductor of the output filter. For convenience of layout and compactness, the input capacitors of the input filter, the gate drivers of the power switches, the capacitors of the de link and the output capacitor of the output filter may be also included in the first component group 101. The integrated circuits for controlling the single-stage dc/dc converter and the dc/ac inverter, and passive components associated with the integrated circuits are included in the second component group 102. Similar to the first implementation, the heat-generating components (e.g., power switches) and non-heat-generating components (e.g., integrated circuits) are separated by the thermal resistance medium. Therefore, the heat-generating components do not cause a significant temperature rise on the non-heat-generating components vulnerable to overheating.

In a fifth implementation of the micro-inverter, the micro-inverter comprises an input filter coupled to a photovoltaic panel, a single-stage dc/ac inverter with galvanic isolation and an output filter. The input filter comprises at least one electrolytic capacitor. The single-stage dc/ac inverter may be implemented as a full-bridge inverter including a transformer.

In the fifth implementation of the micro-inverter, the components of the first component group 101 may comprise the power switches of the of the single-stage dc/ac inverter, the transformer of the single-stage dc/ac inverter and the inductor of the output filter. For convenience of layout and compactness, the gate drivers of the power switches and the output capacitor of the output filter may be also included in the first component group 101. The electrolytic capacitor, the integrated circuits for controlling the single-stage dc/ac inverter and passive components associated with the integrated circuits are included in the second component group 102. Similar to the first implementation, the heat-generating components (e.g., power switches) and non-heat-generating components (e.g., integrated circuits) are separated by the thermal resistance medium. Therefore, the heat-generating components do not cause a significant temperature rise on the non-heat-generating components vulnerable to overheating.

In a sixth implementation of the micro-inverter, the micro-inverter comprises an input filter coupled to a photovoltaic panel, a single-stage dc/ac inverter without galvanic isolation and an output filter. The input filter does not comprise electrolytic capacitors. Other suitable capacitors such as tantalum capacitors, ceramic capacitors and the like are employed to replace the electrolytic capacitors. The single-stage dc/ac inverter may be implemented as a full-bridge inverter including a transformer.

In the sixth implementation of the micro-inverter, the components of the first component group 101 may comprise the power switches of the of the single-stage dc/ac inverter, the transformer, and the inductor of the output filter. For convenience of layout and compactness, the capacitors of the input filter, the gate drivers of the power switches and the output capacitor of the output filter may be also included in the first component group 101. The integrated circuits for controlling the single-stage dc/ac inverter and passive components associated with the integrated circuits are included in the second component group 102. Similar to the first implementation, the heat-generating components (e.g., power switches) and non-heat-generating components (e.g., integrated circuits) are separated by the thermal resistance medium. Therefore, the heat-generating components do not cause a significant temperature rise on the non-heat-generating components vulnerable to overheating.

In a seventh implementation of the micro-inverter, the micro-inverter comprises an input filter coupled to a photovoltaic panel, a single-stage dc/dc converter with galvanic isolation, a dc link, a dc/ac inverter without galvanic isolation and an output filter. The input filter comprises at least one electrolytic capacitor. The single-stage dc/dc converter may be implemented as any isolated dc/dc converters such as flyback converters, LLC resonant converters, any combinations thereof and the like. The dc/ac inverter may be implemented as a full-bridge inverter.

In the seventh implementation of the micro-inverter, the components of the first component group 101 may comprise the power switches and the transformer of the of the single-stage dc/dc converter, the power switches of the of the dc/ac inverter and the inductor of the output filter. For convenience of layout and compactness, the gate drivers of the power switches, the capacitors of the de link and the output capacitor of the output filter may be also included in the first component group 101. The electrolytic capacitor, the integrated circuits for controlling the single-stage dc/dc converter and the dc/ac inverter, and passive components associated with the integrated circuits are included in the second component group 102. Similar to the first implementation, the heat-generating components (e.g., power switches) and non-heat-generating components (e.g., integrated circuits) are separated by the thermal resistance medium. Therefore, the heat-generating components do not cause a significant temperature rise on the non-heat-generating components vulnerable to overheating.

In an eighth implementation of the micro-inverter, the micro-inverter comprises an input filter coupled to a photovoltaic panel, a single-stage dc/dc converter without galvanic isolation, a dc link, a dc/ac inverter without galvanic isolation and an output filter. The input filter does not comprise electrolytic capacitors. Other suitable capacitors such as tantalum capacitors, ceramic capacitors and the like are employed to replace the electrolytic capacitors. The single-stage dc/dc converter may be implemented as any isolated dc/dc converters such as flyback converters, LLC resonant converters, any combinations thereof and the like. The dc/ac inverter may be implemented as a full-bridge inverter.

In the eighth implementation of the micro-inverter, the components of the first component group 101 may comprise the power switches and the transformer of the of the single-stage dc/dc converter, the power switches of the of the dc/ac inverter and the inductor of the output filter. For convenience of layout and compactness, the input capacitors of the input filter, the gate drivers of the power switches, the capacitors of the de link and the output capacitor of the output filter may be also included in the first component group 101. The integrated circuits for controlling the single-stage dc/dc converter and the dc/ac inverter, and passive components associated with the integrated circuits are included in the second component group 102. Similar to the first implementation, the heat-generating components (e.g., power switches) and non-heat-generating components (e.g., integrated circuits) are separated by the thermal resistance medium. Therefore, the heat-generating components do not cause a significant temperature rise on the non-heat-generating components vulnerable to overheating.

In some embodiments, the components of the first component group 101 are surrounded by a first potting compound material. The first component group 101 is in a first module. The components of the second component group 102 are surrounded by a second potting compound material. The second component group 102 is in a second module.

Each of the plurality of connecting elements 103 comprises three portions. First portions of the plurality of connecting elements 103 are in the first module and surrounded by the first potting compound material. Middle portions of the plurality of connecting elements 103 are surrounded by the thermal resistance medium (e.g., air). Second portions of the plurality of connecting elements 103 are in the second module and surrounded by the second potting compound material.

In some embodiments, the micro-inverter is implemented on two open frame packages. The first component group 101 is on a first open frame package. The second component group 102 is on a second open frame package. The plurality of connecting elements 103 is connected between the first open frame package and the second open frame package.

The first open frame package comprises a first thermally conductive and electrically isolating metal board. The components of the first component group 101 are mounted on the first thermally conductive and electrically isolating metal board. The second open frame package comprises a second thermally conductive and electrically isolating metal board. The components of the second component group 102 are mounted on the second thermally conductive and electrically isolating metal board.

In a first implementation of the open frame package based micro-inverter, a first potting compound material partially covers the components of the first component group 101. A second potting compound material partially covers the components of the second component group 102.

In a second implementation of the open frame package based micro-inverter, a first metal case covers a portion of the components of the first component group 101. A second metal case covers a portion of the components of the second component group 102.

In a third implementation of the open frame package based micro-inverter, a first metal mesh enclosure covers a portion of the components of the first component group 102. A second metal mesh enclosure covers a portion of the components of the second component group 102.

In some embodiments, the metal cases and metal mesh enclosures are used for local electromagnetic interference (EMI) isolation. In some embodiments, the potting compound materials, the metal cases and metal mesh enclosures are used for local heat dissipation. In some embodiments, the potting compound materials, the metal cases and metal mesh enclosures are used to partially protect components in harsh environments.

In some embodiments, an electrolytic capacitor is electrically coupled to the first component group 101. The electrolytic capacitor and heat generating components (e.g., power switches and magnetic devices) of the first component group 101 are in two different modules. The two different modules are separated by the thermal resistance medium.

In some embodiments, an electrolytic capacitor is electrically coupled to the first component group 101. The electrolytic capacitor, the first component group 101 and the second component group 102 are in three different modules. The three different modules are separated by the thermal resistance medium.

In some embodiments, the first component group 101 is in a first module. The first board is a fast heat-conducting board, and a first potting compound material partially covers the components of the first component group 101. The second component group 102 is in a second module. The second board is a printed circuit board, and a second potting compound material partially covers the components of the second component group 102.

In some embodiments, the first component group 101 is in a first module. The first board is a fast heat-conducting board, and a first metal shielding case covers the components of the first component group 101. The second component group 102 is in a second module. The second board is a printed circuit board and a second metal shielding case covers the components of the second component group 102.

In some embodiments, the first component group 101 is in a first module. The first board is a fast heat-conducting board, and a first metal mesh enclosure covers the components of the first component group 101. The second component group 102 is in a second module. The second board is a printed circuit board, and a second metal mesh enclosure covers the components of the second component group 102.

The components of a micro-inverter can be categorized into two groups. A first group (e.g., the first component group 101 shown in FIG. 2) includes about 30% of the total components of the micro-inverter. The 30% of the total components are heat-generating components such as power switches and magnetic devices. A second group (e.g., the second component group 102 shown in FIG. 2) includes about 70% of the total components of the micro-inverter. The 70% of the total components generate no heat or little heat. The second group comprises a variety of control and signal processing circuits such as a controller configured to control the operation of the micro-inverter.

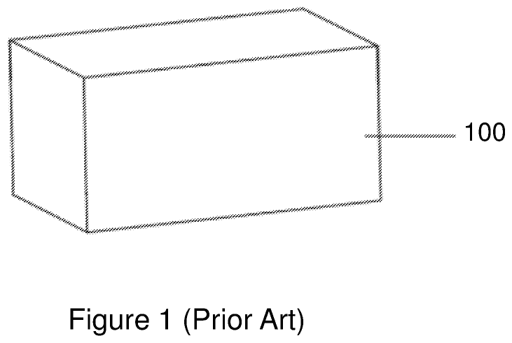

In the existing packaging of the micro-inverter shown in FIG. 1, because heat is radiated from the inside to the outside, the temperature inside must be higher than the outside. The typical temperature difference is about 20 degrees.

In operation, assuming that the temperature of the chassis on the first component group (heat-generating components) is 100 degrees, the temperature of the components of the second component group that are isolated from the heat will be much lower than the temperature of the chassis on the hot side (the first component group), such as 70 degrees. In this case, the temperature difference between the micro-inverter shown in FIG. 2 and the conventional micro-inverter (all components in one package) is about 30 degrees (100 degrees-70 degrees) plus 20 degrees (the inside temperature is about 20 degrees higher than the chassis) which is 50 degrees. The temperature of 70% of the components will be lower than the temperature of the non-heat-generating components of the brick package shown in FIG. 1. The temperature is reduced by 50 degrees. It is known that for every ten degrees decrease in temperature, the life span of a component (e.g., electrolytic capacitor) is extended by 50%. Then, the life of the 70% of the components will be extended by 32 times. This is a significant life improvement.

A large amount of data shows that micro-inverter failures are caused by the 70% of the components (non-heat-generating components). Therefore, by employing the packaging configuration shown in FIG. 2, the life of the micro-inverter will be greatly improved.

Electrolytic capacitors are the most important components in the micro-inverter for its life. From a theoretical analysis, electrolytic capacitors are the components with the shortest life in the micro-inverter design. If the electrolytic capacitor is packaged in the micro-inverter using the existing method as shown in FIG. 1, then if the outside temperature is 100 degrees, the temperature of the electrolytic capacitor will be in a range from about 110 degrees to about 120 degrees. In comparison, as shown in FIG. 2, the electrolytic capacitor is in the second component group 102. The electrolytic capacitor is separated from the heat-generating components.

In operation, the temperature of the first component group 101 (heat-generating components) is 100 degrees. At the same time, the temperature of the second group is in a range from about 70 degrees to about 80 degrees. The maximum temperature of the electrolytic capacitor is 80 degrees. Compared with the original one shown in FIG. 1, from 120 degrees to 80 degrees, the temperature of the electrolytic capacitor is reduced by 40 degrees, which is equivalent to increasing the life of the electrolytic capacitor by 16 times.

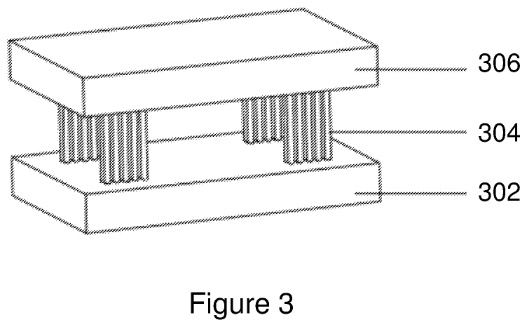

FIG. 3 illustrates a first implementation of the power conversion apparatus shown in FIG. 2 in accordance with various embodiments of the present disclosure. The components of a micro-inverter are divided into two groups. A first component group includes hot components. In other words, the components of the first component group are heat-generating components. This group corresponds to the first component group 101 shown in FIG. 2. A second component group includes cold components. In other words, the components of the second component group generate no heat or little heat. This group corresponds to the second component group 102 shown in FIG. 2.

In some embodiments, the components of the second component group (non-heat-generating components) are packaged in a bottom module 302. In some embodiments, the bottom module 302 may be formed by applying a potting compound material over a board on which the non-heat-generating components are mounted. The components of the second component group (the heat-generating components) are packaged in a top module 306. In some embodiments, the top module 306 may be formed by applying a potting compound material over a board on which the heat-generating components are mounted. These two modules are connected by various cables 304. The non-heat-generating components and heat-generating components are separated by a thermal resistance medium such as air. Since the non-heat-generating components is separated from the heat-generating components by air, the temperature of the cold component (non-heat-generating components) will be much lower than the hot component (heat-generating components). In some embodiments, the temperature difference is about 30 degrees. Such a temperature difference helps improve the lifespan of the non-heat-generating components, thereby improving the longevity of the micro-inverter.

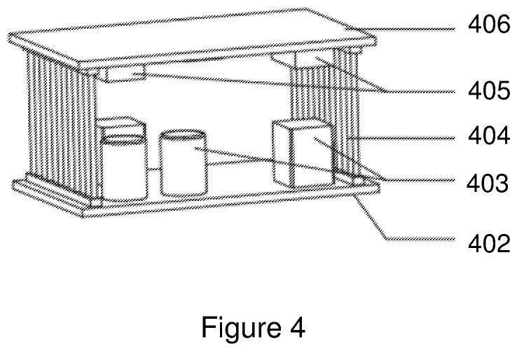

FIG. 4 illustrates the implementation of the first component group and the second component group shown in FIG. 3 in accordance with various embodiments of the present disclosure. The bottom module 302 (shown in FIG. 3) includes a bottom board 402 and a plurality of non-heat-generating components 403 mounted on the bottom board 402. The top module 306 (shown in FIG. 3) includes a top board 406 and a plurality of heat-generating components 405 mounted on the top board 406.

In some embodiments, the top board 406 is implemented as a fast thermal conductivity substrate such as an aluminum-based board. The bottom board is implemented as a printed circuit board such as a FR4 printed circuit board (PCB).

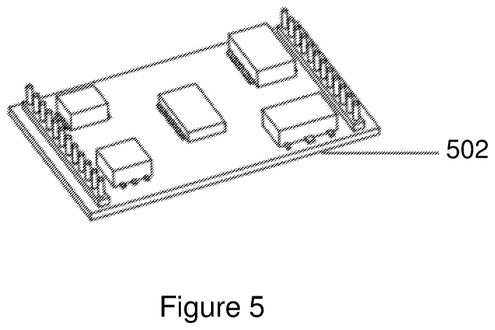

FIG. 5 illustrates a second implementation of the power conversion apparatus shown in FIG. 2 in accordance with various embodiments of the present disclosure. All heat-generating components are placed on a fast heat-conducting substrate 502. All heat-generating components are exposed to the air.

As shown in FIG. 5, All heat-generating components are placed on the fast heat-conducting substrate 502. Assuming that the chassis is 100 degrees, all heat-generating components are 20 degrees lower than the temperature (e.g., 120 degrees) of the original package shown in FIG. 1.

The packaging technology shown in FIG. 5 can also be summarized as open frame package technology, which is to put all the thermal components on a layer of a fast thermal conductivity substrate. The fast thermal conductivity substrate may be implemented as an aluminum substrate, a ceramic substrate and the like. The heat-generating components are mounted on the fast thermal conductivity substrate. The other components that are not hot are placed on an FR4 board. The FR4 board and the fast thermal conductive substrate are electrically connected through a plurality of connecting elements such as PCB through-hole pins. The heat conduction between the fast thermal conductive substrate and the FR4 board is blocked. The blocking medium can be air or other non-thermal conductive materials.

In this implementation, most of the non-heat generating components are on the FR4 board. As a result, its temperature will be much lower than that on the fast thermal conductivity substrate, because the two of them use thermal insulation materials (such as air) to separate the heat.

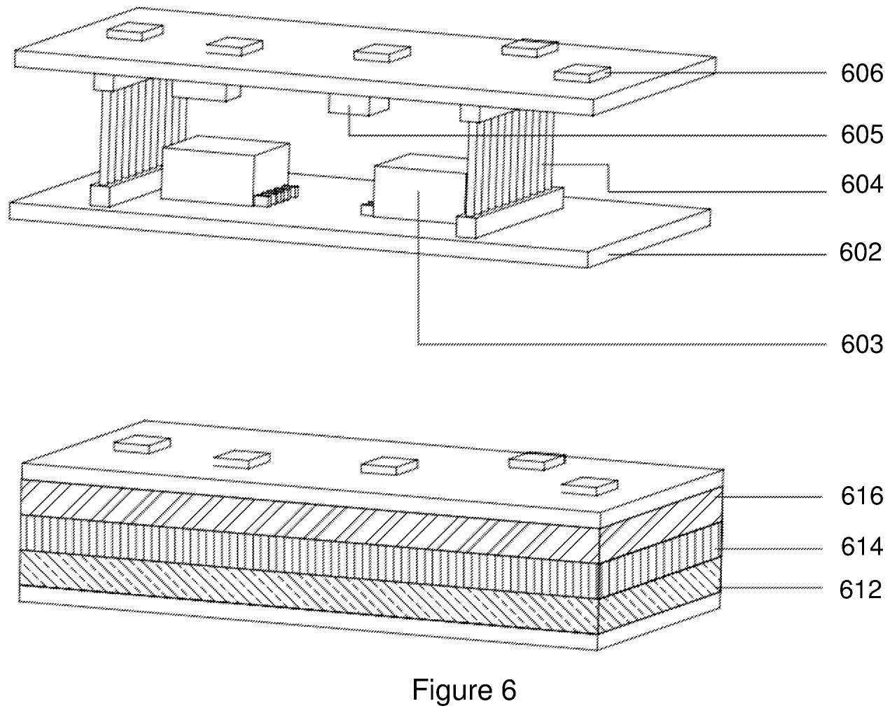

FIG. 6 illustrates a third implementation of the power conversion apparatus shown in FIG. 2 in accordance with various embodiments of the present disclosure. The power conversion apparatus shown in FIG. 6 is a micro-inverter. The components of the power conversion apparatus are divided into two groups. A first component group 603 comprises power switches and magnetic devices. A second component group 605 comprises the rest components including at least one integrated circuit. The components of the first component group 603 are heat-generating elements configured to generate more heat than components of the second component group 605.

The components of the first component group 603 are mounted on a first board 602. In some embodiments, the first board 602 is a fast heat-conducting board. The fast heat-conducting board may be implemented as an aluminum substrate, a ceramic substrate and the like. The components of the second component group 605 are mounted on a second board 606. In some embodiments, the second board 606 is a printed circuit board. A plurality of connecting elements 604 is connected between the first board 602 and the second board 606. In some embodiments, the plurality of connecting elements 604 is implemented as connecting pins as shown in FIG. 6.

FIG. 6 further illustrates three potting compound layers formed between the first board 602 and the second board 606. In the process of forming the three potting compound layers, four sidewalls may be temporarily placed between the first board 602 and the second board 606. A first potting compound layer 612 is formed over the first board 602 using a first liquid potting compound material such as epoxy potting compounds. In some embodiments, a topmost surface of the first component group 603 is lower than a top surface of the first potting compound layer 612. A suitable hardening process such as a curing process is applied to the first potting compound layer 612. Once the hardening process is finished, a second potting compound layer 614 is formed over the first potting compound layer 612 using a second liquid potting compound material. A bottommost surface of the second component group 605 is higher than a top surface of the second potting compound layer 614.

In some embodiments, the second liquid potting compound material is a compound material with low thermal conductivity. Materials such as certain epoxy formulations, silicone rubbers, or polyurethane compounds may be selected for their insulating properties.

A suitable hardening process such as a curing process is applied to the second potting compound layer 614. Once the hardening process is finished, a third potting compound layer 616 is over the second potting compound layer 614 using a third liquid potting compound material. A topmost surface of the third potting compound layer 616 is in contact with the second board 606. In some embodiments, the third liquid potting compound material is similar to the first liquid potting compound material. A suitable hardening process such as a curing process is applied to the third potting compound layer 616.

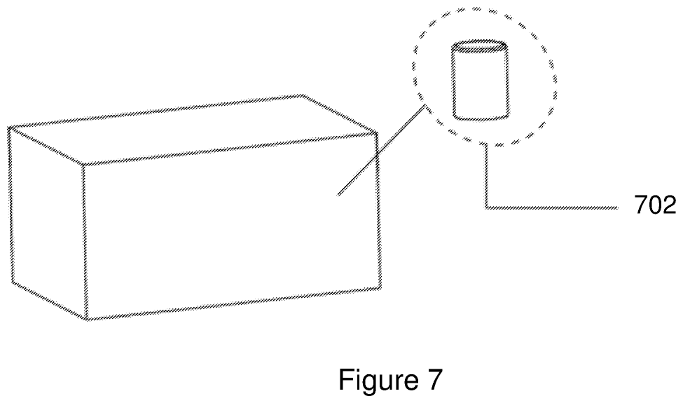

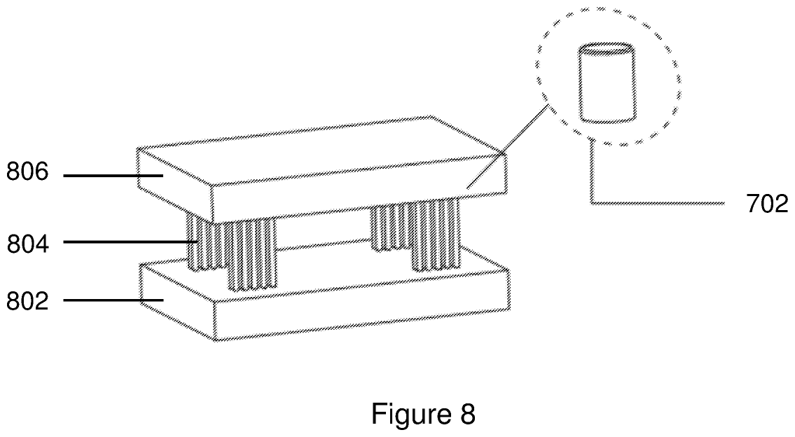

FIGS. 7 and 8 illustrate a fourth implementation of the power conversion apparatus shown in FIG. 2 in accordance with various embodiments of the present disclosure. As shown in FIG. 7, electrolytic capacitors 702 are embedded in a module. In some embodiments, this module is separated from the module where the heat-generating components are located. FIG. 8 illustrates a micro-inverter comprising at least one electrolytic capacitor.

As shown in FIG. 8, the components of a micro-inverter are divided into two groups. A first component group 802 includes heat-generating components (e.g., power switches). A second component group 806 includes electrolytic capacitors 702 and components (e.g., integrated circuits) generating no heat or little heat.

As shown in FIG. 8, the heat-generating components are packaged in a bottom module. The heat-generating components are mounted on a board in the bottom module. The rest components, especially the electrolytic capacitors 702, are packaged in a top module. The formation process of the bottom module and the top module is similar to that discussed above with respect to FIG. 3, and hence is not discussed again herein. These two modules are connected by various connecting elements 804. In some embodiments, the terminal leads of the electrolytic capacitors 702 are part of the connecting elements 804. For each electrolytic capacitor, the main body of the electrolytic capacitor is in the top module. The terminal leads of the electrolytic capacitor function as the connecting elements. The bottommost surface of the terminal leads of the electrolytic capacitor are connected to the board in the bottom module. Furthermore, the connecting areas between the terminal leads and the main body are covered by suitable sealing materials such as epoxy resin. The sealing material may form a trapezoidal area surrounding the terminal lead. In some embodiments, the bottommost surface of the trapezoidal area is level with the surface of the bottom module.

The heat-generating components and the non-heat-generating components are separated by a thermal resistance medium such as air. Since the non-heat-generating components are separated from the heat-generating components by air, the temperature of the cold component (non-heat-generating components) will be much lower than the hot component (heat-generating components). In some embodiments, the temperature difference is about 30 degrees. Such a temperature difference helps improve the lifespan of the electrolytic capacitors, thereby improving the longevity of the micro-inverter.

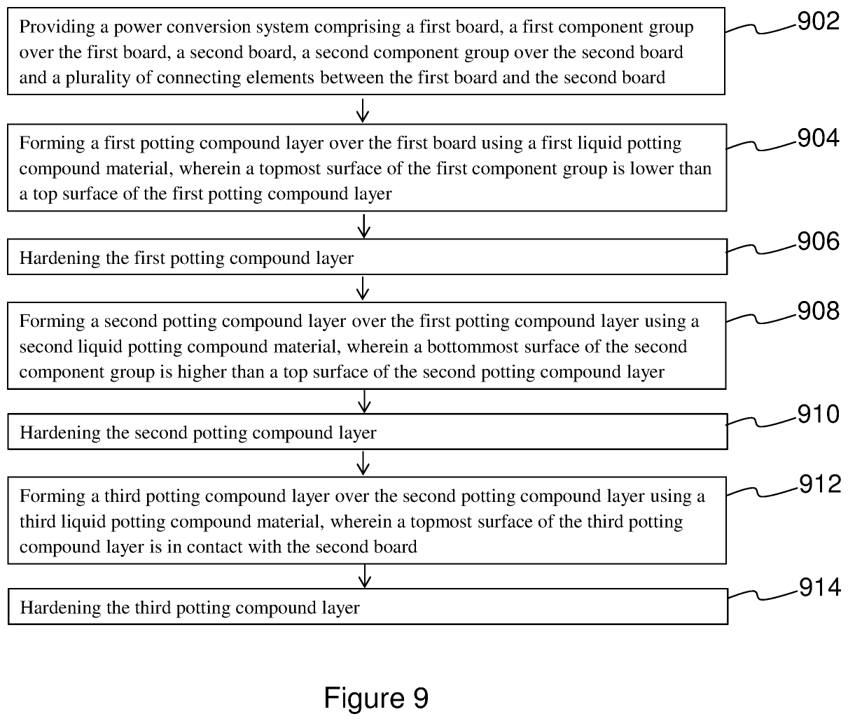

FIG. 9 illustrates a flow chart of a method for fabricating the power conversion apparatus shown in FIG. 6 in accordance with various embodiments of the present disclosure. This flowchart shown in FIG. 9 is merely an example, which should not unduly limit the scope of the claims. One of ordinary skill in the art would recognize many variations, alternatives, and modifications. For example, various steps illustrated in FIG. 9 may be added, removed, replaced, rearranged and repeated.

At step 902, a power conversion system is provided. The power conversion system comprises a first board (e.g., the first board 602), a first component group (e.g., the first component group 603) over the first board, a second board (e.g., the second board 606), a second component group (e.g., the second component group 605) over the second board and a plurality of connecting elements (e.g., the connecting elements 604) between the first board and the second board.

At step 904, a first potting compound layer (e.g., the first potting compound layer 612) is formed over the first board using a first liquid potting compound material. A topmost surface of the first component group is lower than a top surface of the first potting compound layer.

At step 906, the first potting compound layer is hardened through a suitable hardening process.

At step 908, a second potting compound layer (e.g., the second potting compound layer 614) is formed over the first potting compound layer using a second liquid potting compound material. A bottommost surface of the second component group is higher than a top surface of the second potting compound layer.

At step 910, the second potting compound layer is hardened through a suitable hardening process.

At step 912, a third potting compound layer (e.g., the third potting compound layer 616) is formed over the second potting compound layer using a third liquid potting compound material, wherein a topmost surface of the third potting compound layer is in contact with the second board.

At step 914, the third potting compound layer is hardened through a suitable hardening process.

The power conversion system described above is a micro-inverter. The first component group comprises power switches and magnetic devices. The second component group comprises one integrated circuit.

Components of the first component group are heat-generating elements configured to generate more heat than components of the second component group. The first board is a fast heat-conducting board. The second board is a printed circuit board.

Components of the first component group are embedded in the first potting compound layer. At least one component of the second component group is embedded in the third potting compound layer. Middle portions of the plurality of connecting elements are surrounded by the second potting compound layer comprising a thermal resistance medium.

The embodiments described above are also applicable to the powertrain of an EV. An EV car may comprise an on-board charger (OBC), a dc/dc converter and a motor drive system.

The components of the on-board charger of the EV car can be categorized into two groups, namely a first component group (a non-heat-generating component group) and a second component group (a heat-generating component group). The first component group and the second component group can be packaged into at least two different modules. The first component group and the second component group are separated by the thermal resistance medium.

The components of the dc/dc converter of the EV car can be categorized into two groups, namely a first component group (a non-heat-generating component group) and a second component group (a heat-generating component group). The first component group and the second component group can be packaged into at least two different modules. The first component group and the second component group are separated by the thermal resistance medium.

The components of the motor drive system of the EV car can be categorized into two groups, namely a first component group (a non-heat-generating component group) and a second component group (a heat-generating component group). The first component group and the second component group can be packaged into at least two different modules. The first component group and the second component group are separated by the thermal resistance medium.

The embodiments described above are also applicable to the base stations of the advanced communication systems (e.g., 5G wireless communication systems). A base station may comprise an ac/dc converter, a plurality of dc/dc converters and a battery charger. The components of each power converter in the base station can be categorized into two groups, namely a first component group (a non-heat-generating component group) and a second group (a heat-generating component group). The first component group and the second component group can be packaged into at least two different modules. The first component group and the second component group are separated by the thermal resistance medium. Furthermore, the first component groups of a plurality of power converters can be packaged in a first module. The second component groups of the plurality of power converters can be packaged in a second module. The first and second modules are separated by the thermal resistance medium. Moreover, the first component groups of all power converters (the ac/dc converter, the plurality of dc/dc converters and the battery charger) can be packaged in a first module. The second component groups of the corresponding power converters can be packaged in a second module. The first and second modules are separated by the thermal resistance medium.

The embodiments described above are also applicable to the power supplies of the Wi-Fi transmission and receiving stations, and other outdoor power supplies. The components of these power supplies can be categorized into two groups, namely a first component group (a non-heat-generating component group) and a second group (a heat-generating component group). The first component group and the second component group can be packaged into at least two different modules. The first component group and the second component group are separated by the thermal resistance medium.

Although embodiments of the present disclosure and its advantages have been described in detail, it should be understood that various changes, substitutions and alterations can be made herein without departing from the spirit and scope of the disclosure as defined by the appended claims.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. An apparatus comprising:
a first component group on a first board;
a second component group on a second board, wherein components of the first component group are heat-generating elements configured to generate more heat than components of the second component group; and
a plurality of connecting elements electrically coupled between the first component group and the second component group, wherein portions of the plurality of connecting elements are in a thermal resistance medium, and the first component group and the second component group are separated by the thermal resistance medium.

2. The method of claim 1, wherein:
the thermal resistance medium is air;
the first board is a fast heat-conducting board; and
the second board is a printed circuit board.

3. The apparatus of claim 2, wherein:
the fast heat-conducting board is thermally conductive and electrically isolating ceramic printed circuit board.

4. The apparatus of claim 2, wherein:
the fast heat-conducting board is a thermally conductive and electrically isolating metal board having a metallic support plate, a dielectric layer over the metallic support plate and a circuit layer over the dielectric layer, and wherein the metallic support plate is made of aluminum, and the circuit layer is made of copper.

5. The apparatus of claim 1, wherein:
the components of the first component group comprise power switches and magnetic devices; and
the components of the second component group comprise at least one electrolytic capacitor.

6. The apparatus of claim 1, wherein:
the first component group is in a first module, and wherein the components of the first component group are surrounded by a first potting compound material; and
the second component group is in a second module, and wherein the components of the second component group are surrounded by a second potting compound material, and wherein:
first portions of the plurality of connecting elements are in the first module and surrounded by the first potting compound material;
middle portions of the plurality of connecting elements are surrounded by the thermal resistance medium; and
second portions of the plurality of connecting elements are in the second module and surrounded by the second potting compound material.

7. The apparatus of claim 1, wherein:
the first component group is on a first open frame package; and
the second component group is on a second open frame package, and wherein the plurality of connecting elements is connected between the first open frame package and the second open frame package.

8. The apparatus of claim 7, wherein:
the first open frame package comprises a first thermally conductive and electrically isolating metal board and the components of the first component group mounted on the first thermally conductive and electrically isolating metal board; and
the second open frame package comprises a second thermally conductive and electrically isolating metal board and the components of the second component group mounted on the second thermally conductive and electrically isolating metal board.

9. The apparatus of claim 8, wherein:
a first potting compound material partially covers the components of the first component group; and
a second potting compound material partially covers the components of the second component group.

10. The apparatus of claim 8, wherein:
a first metal case covers a portion of the components of the first component group; and
a second metal case covers a portion of the components of the second component group.

11. The apparatus of claim 8, wherein:
a first metal mesh enclosure covers a portion of the components of the first component group; and
a second metal mesh enclosure covers a portion of the components of the second component group.

12. The apparatus of claim 1, further comprising:
at least one electrolytic capacitor electrically coupled to the first component group, wherein the at least one electrolytic capacitor and the first component group are in two different modules, and wherein:
terminal leads of the at least one electrolytic capacitor are part of the plurality of connecting elements; and
the two different modules are separated by the thermal resistance medium.

13. The apparatus of claim 1, wherein:
the first component group is in a first module, and wherein the first board is a fast heat-conducting board and a first potting compound material partially covers the components of the first component group; and
the second component group is in a second module, and wherein the second board is a printed circuit board and a second potting compound material partially covers the components of the second component group.

14. The apparatus of claim 1, wherein:
the first component group is in a first module, and wherein the first board is a fast heat-conducting board and a first metal shielding case covers the components of the first component group; and
the second component group is in a second module, and wherein the second board is a printed circuit board and a second metal shielding case covers the components of the second component group.

15. The apparatus of claim 1, wherein:
the first component group is in a first module, and wherein the first board is a fast heat-conducting board and a first metal mesh enclosure covers the components of the first component group; and
the second component group is in a second module, and wherein the second board is a printed circuit board and a second metal mesh enclosure covers the components of the second component group.

16. The apparatus of claim 1, wherein:
components of the first component group are on a first side of the first board;
at least one component of the second component group is on a first side of the second board;
at least one component of the second component group is on a second side of the second board; and
the plurality of connecting elements is electrically coupled between the first side of the first board and the first side of the second board.

17. A micro-inverter comprising:
power switches and magnetic devices on a first board;
a control integrated circuit on a second board; and
a plurality of signal and power channels coupled between the first board and the second board, wherein power and a plurality of signals flow through a thermal resistance medium placed between the first board and the second board.

18. The micro-inverter of claim 17, further comprising:
a first potting compound layer in contact with the first board;
a third potting compound layer in contact with the second board; and
a second potting compound layer is between the first potting compound layer and the third potting compound layer, wherein the second potting compound layer comprises the thermal resistance medium.

19. The micro-inverter of claim 18, wherein the plurality of signal and power channels is implemented as a plurality of cables, and wherein:
the power switches and the magnetic devices are embedded in the first potting compound layer;
the control integrated circuit is embedded in the third potting compound layer; and
middle portions of the plurality of cables are surrounded by the second potting compound layer.

20. The micro-inverter of claim 17, further comprising:
an electrolytic capacitor on the second board, wherein terminal leads of the electrolytic capacitor are part of the plurality of signal and power channels, and wherein bottommost surfaces of the terminal leads of the electrolytic capacitor are in direct contact with the first board.

21. The micro-inverter of claim 17, wherein the plurality of signal and power channels comprises a plurality of cables and a wireless power transfer channel, and wherein:
the power switches and the magnetic devices are embedded in a first potting compound layer in contact with the first board;
the control integrated circuit is embedded in a third potting compound layer in contact with the second board;
middle portions of the plurality of cables are surrounded by a second potting compound layer formed between the first potting compound layer and the third potting compound layer; and
the wireless power transfer channel is configured to provide bias power for the power switches on the first board.

22. A method comprising:
providing a power conversion system comprising a first board, a first component group over the first board, a second board, a second component group over the second board and a plurality of connecting elements between the first board and the second board;
forming a first potting compound layer over the first board using a first liquid potting compound material, wherein a topmost surface of the first component group is lower than a top surface of the first potting compound layer;
hardening the first potting compound layer;
forming a second potting compound layer over the first potting compound layer using a second liquid potting compound material, wherein a bottommost surface of the second component group is higher than a top surface of the second potting compound layer;
hardening the second potting compound layer;
forming a third potting compound layer over the second potting compound layer using a third liquid potting compound material, wherein a topmost surface of the third potting compound layer is in contact with the second board; and
hardening the third potting compound layer.

23. The method of claim 22, wherein:
the power conversion system is a micro-inverter;
the first component group comprises power switches and magnetic devices; and
the second component group comprises one integrated circuit.

24. The method of claim 22, wherein:
components of the first component group are heat-generating elements configured to generate more heat than components of the second component group;
the first board is a fast heat-conducting board; and
the second board is a printed circuit board.

25. The method of claim 22, wherein:
components of the first component group are embedded in the first potting compound layer;
at least one component of the second component group is embedded in the third potting compound layer; and
middle portions of the plurality of connecting elements are surrounded by the second potting compound layer comprising a thermal resistance medium.
